(19) United States
(12) Patent Application Publication
(10) Pub. No.: US 2016/0155753 A1
(43) Pub. Date: Jun. 2, 2016

(54) DISPLAY DEVICE

(71) Applicant: Samsung Display Co. Ltd., Yongin-City (KR)

(72) Inventors: MASATAKA KANO, Hwaseong-si (KR); Yeon Keon MOON, Seoul (KR); Jung Hun NOH, Yongin-si (KR); Jun Hyung LIM, Seoul (KR); So Young KOO, Yongin-si (KR); Myoung Hwa KIM, Seoul (KR)

(21) Appl. No.: 14/664,589

(22) Filed: Mar. 20, 2015

(30) Foreign Application Priority Data
Dec. 2, 2014 (KR) 10-2014-0170204

(51) Int. Cl. H01L 27/12; H01L 29/786

(52) U.S. Cl. CPC H01L 27/124; H01L 27/1248; H01L 29/78606

(57) ABSTRACT

The display device includes a substrate, a first gate line extending in a first direction on the substrate, a gate insulating layer formed on the substrate to cover the first gate line, a first semiconductor pattern formed on the gate insulating layer to overlap the first gate line, and including a first region and a second region, a first data line extending in a second direction that is crossing the first gate line on the gate insulating layer, and including a source electrode region that overlaps the first region of the first semiconductor pattern, a drain electrode spaced apart from the source electrode region and formed on the second region of the first semiconductor pattern, and a pixel electrode formed on the drain electrode and electrically connected to the drain electrode. The first semiconductor pattern is arranged in a third direction between the first direction and the second direction.

### CROSS-REFERENCE TO RELATED APPLICATIONS

This application is based on and claims priority to Korean Patent Application No. 10-2014-0170204, filed on Dec. 2, 2014 in the Korean Intellectual Property Office, the disclosure of which is incorporated herein in its entirety by reference.

### BACKGROUND

1. Field

The present inventive concept relates to a display device.

2. Description of the Related Art

A liquid crystal display, which is one of display devices that have been widely used, is a display device that controls light pass through a liquid crystal layer by applying a voltage to electrodes (a pixel electrode and a common electrode) which are formed on two opposite substrates to alter an arrangement of liquid crystal molecules of a liquid crystal layer interposed between the two substrates.

Such a liquid crystal display includes thin film transistors connected to pixel electrodes. The thin film transistors are used as switching elements that independently drive respective pixels in a display device, such as a liquid crystal display or an organic light emitting display.

Specifically, the thin film transistor is a switching element which controls a data signal that is provided to a pixel electrode through a data line according to a gate signal that is provided through a gate line, and includes a gate electrode connected to the gate line, an active layer (semiconductor layer) forming a channel, a source electrode connected to the data line, and a drain electrode that is spaced apart from the source electrode.

### SUMMARY

A liquid crystal display having high resolution has recently been developed. In such a liquid crystal display having high resolution, as the resolution is increased, the size of a thin film transistor should be decreased. However, there has been a limit in decreasing the size of the thin film transistor. Accordingly, the aperture ratio of a pixel has been decreased in a liquid crystal display having high resolution.

Accordingly, one subject to be solved by the present inventive concept is to provide a display device, which can increase the aperture ratio of a pixel while implementing high resolution.

Additional advantages, subjects, and features of the inventive concept will be set forth in part in the description which follows and in part will become apparent to those having ordinary skill in the art upon examination of the following or may be learned from practice of the inventive concept.

In one aspect of the present inventive concept, there is provided a display device including: a substrate; a first gate line extending in a first direction on the substrate; a gate insulating layer formed on the substrate to cover the first gate line; a first semiconductor pattern formed on the gate insulating layer to overlap the first gate line, and including a first region and a second region; a first data line extending in a second direction that is crossing the first gate line on the gate insulating layer, and including a source electrode region that overlaps the first region of the first semiconductor pattern; a drain electrode spaced apart from the source electrode region and formed on the second region of the first semiconductor pattern; and a pixel electrode formed on the drain electrode and electrically connected to the drain electrode, wherein the first semiconductor pattern is arranged in a third direction between the first direction and the second direction.

The first region and the second region of the first semiconductor pattern may be on a straight line.

A width of the source electrode region may be equal to a width of the first data line which does not overlap the first region of the first semiconductor pattern.

The first semiconductor pattern may comprise a third region that connects the first region and the second region to each other, and the first region and the second region of the first semiconductor pattern may completely overlap the source electrode and the drain electrode, respectively.

The first semiconductor pattern may include a third region that connects the first region and the second region to each other, and the first region and the second region of the first semiconductor pattern may partially overlap the source electrode and the drain electrode, respectively.

Areas of the first region and the second region of the first semiconductor pattern may be smaller than areas of the source electrode region and the drain electrode, respectively.

Planar shapes of the first region and the second region of the first semiconductor pattern may be rectangular or partially rounded.

The display device may further include: a second semiconductor pattern formed on the gate insulating layer to overlap the first gate line, spaced apart from the first semiconductor pattern in the first direction, and including a first region and a second region; and a second data line extending in the second direction on the gate insulating layer, spaced apart from the first data line in the first direction, and including a source electrode region overlapping the first region of the second semiconductor pattern, wherein the second semiconductor pattern may be arranged in the third direction, and a minimum gap distance between the second region of the first semiconductor pattern and the first region of the second semiconductor pattern may be equal to or larger than 2 μm.

The display device may further include an etch stopper layer formed on the gate insulating layer to cover the first semiconductor pattern between the first semiconductor pattern and the first data line, wherein the etch stopper layer may include a first through-hole for connecting the source electrode region of the first data line to the first region of the first semiconductor pattern, and a second through-hole for connecting the drain electrode to the second region of the first semiconductor pattern.

A maximum width of the source electrode region and a maximum width of the drain electrode may be larger than a width of the first through-hole and a width of the second through-hole, respectively.

A width of the first data line except for the source electrode region may be smaller than a width of the source electrode region.

The first region and the second region of the first semiconductor pattern may completely overlap the source electrode region and the drain electrode, respectively.

Planar shapes of the first region and the second region of the first semiconductor pattern may be circular.

The display device may further include: a second semiconductor pattern formed on the gate insulating layer to overlap the first gate line, spaced apart from the first semiconductor pattern in the first direction, and including a first region and a second region; and a second data line that extending in the second direction on the gate insulating layer, spaced apart from the first data line in the first direction, and including a source electrode region overlapping the first region of the second semiconductor pattern, wherein the second semiconductor pattern may be arranged in the third direction, and a minimum gap distance between the second region of the first semiconductor pattern and the first region of the second semiconductor pattern is equal to or larger than 2 μm.

The display device may further include a protection layer interposed between the gate insulating layer and the pixel electrode, and formed to cover the first semiconductor pattern, the data lines, and the drain electrode, wherein the protection layer may include a contact hole that overlaps the second region of the first semiconductor pattern and the drain electrode.

An angle between the first semiconductor pattern and the first data line may be 45°.

According to the embodiments of the present inventive concept, at least the following effects can be achieved.

Since the display device according to an embodiment of the present inventive concept is provided with the thin film transistor including the semiconductor pattern arranged in the third direction that is between the first direction in which the gate line extends and the second direction in which the data line extends and the source electrode region that is included in the data line, the minimum distance can be secured between the semiconductor patterns between the adjacent pixels, and the region that is occupied by the thin film transistor in one pixel can be reduced in both the first and second directions.

Accordingly, in the display device according to an embodiment of the present inventive concept, high resolution can be implemented, and when the semiconductor pattern is formed using the photolithography process, the occurrence of the misalignment can be reduced, and the deterioration of the aperture ratio of the pixel can be reduced.

The effects according to the present inventive concept are not limited to the contents as exemplified above, but further various effects are included in the description.

### BRIEF DESCRIPTION OF THE DRAWINGS

The above and other objects, features and advantages of the present inventive concept will be more apparent from the following detailed description taken in conjunction with the accompanying drawings, in which:

FIG. 1 is a perspective view of a display device which includes a first panel and a second panel according to an embodiment of the present inventive concept;

FIG. 2 is a plan view of a first display panel of FIG. 1;

FIG. 3 is a cross-sectional view of the display panel of FIG. 2 taken along line A-A′of FIG. 2;

FIG. 4 is a plan view of a thin film transistor of FIG. 2;

FIG. 5 is a plan view illustrating another shape of a semiconductor pattern of FIG. 4;

FIG. 6 is a plan view illustrating an arrangement of neighboring thin film transistors of FIG. 2;

FIG. 7 is a plan view of a first display panel of a display panel according to another embodiment of the present inventive concept;

FIG. 8 is a cross-sectional view of the display panel of FIG. 7 taken along line B-B′ of FIG. 7;

FIG. 9 is a plan view of a thin film transistor of one pixel of FIG. 7;

FIG. 10 is a plan view illustrating an arrangement of neighboring thin film transistors of FIG. 7; and

FIG. 11 is a plan view illustrating the arrangement of a semiconductor pattern, an etch stopper layer, a source electrode region, and a drain electrode of FIG. 8.

### DETAILED DESCRIPTION

Advantages and features of the present inventive concept and methods of accomplishing the same may be understood more readily by reference to the following detailed description of exemplary embodiments and the accompanying drawings. The present inventive concept may, however, be embodied in many different forms and should not be construed as being limited to the embodiments set forth herein. Rather, these embodiments are provided so that this disclosure will be thorough and complete and will fully convey the concept of the inventive concept to those skilled in the art, and the present inventive concept will only be defined by the appended claims.

It will also be understood that when a layer is referred to as being “on” another layer or substrate, it can be directly on the other layer or substrate, or intervening layers may also be present between the layer and the another layer. The same reference numbers indicate the same components throughout the specification.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present inventive concept.

Hereinafter, embodiments of the present inventive concept will be described with reference to the accompanying drawings.

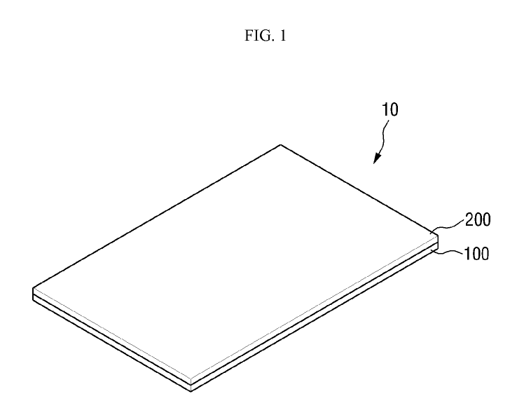

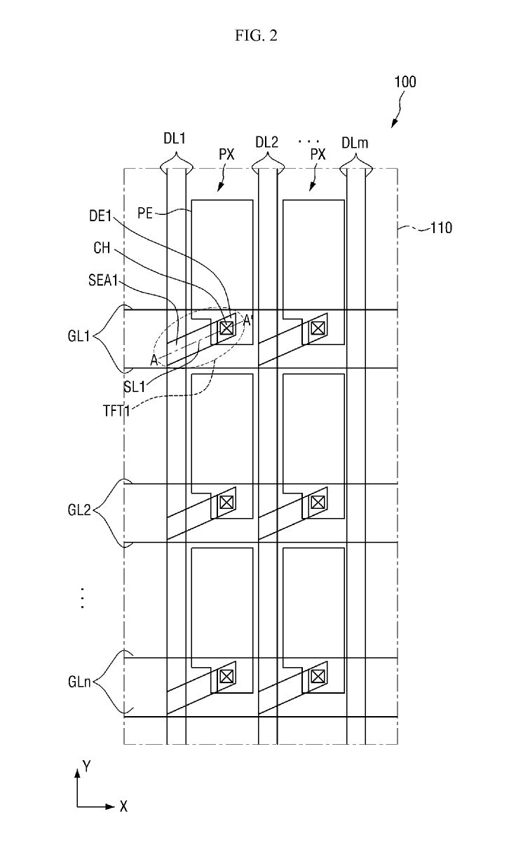

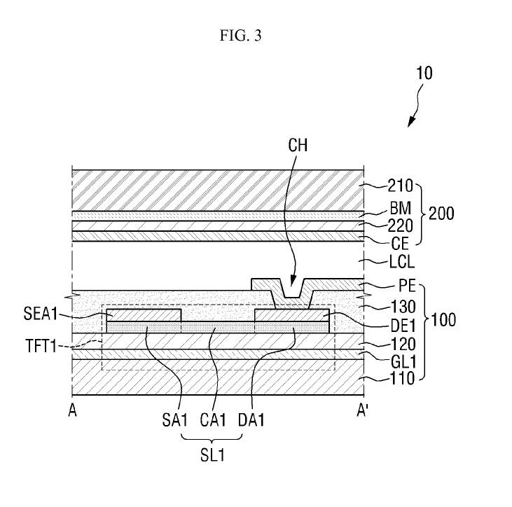

FIG. 1 is a perspective view of a display device according to an embodiment of the present inventive concept. FIG. 2 is a plan view of a first display panel of FIG. 1, and FIG. 3 is a cross-sectional view of the display panel of FIG. 2 taken along line A-A′ of FIG. 2.

A display device 10 is a device that has a plurality of pixels to display an image. Although not specially limited, the display device 10 may be, for example, a liquid crystal display, an organic light emitting display, an electrophoretic display, an electrowetting display, or a MEMS (MicroElectroMechanical System) display. According to the present inventive concept, a case where the display device 10 is implemented by a liquid crystal display is exemplified.

Referring to FIGS. 1 to 3, the display device 10 according to an embodiment of the present inventive concept includes a first panel 100, a second panel 200 that faces the first panel 100, and a liquid crystal layer LCL formed between the first panel 100 and the second panel 200. Although not illustrated, the display device 10 may further include a backlight unit that provides light to the display device 10.

The first panel 100 may include a first substrate 110, gate lines GL1 to GLn (n is a natural number), a gate insulating layer 120, a semiconductor pattern SL1, data lines DL1 to DLm (m is a natural number), a drain electrode DE1, a protection layer 130, and a pixel electrode PE.

The first substrate 110 may be a transparent insulating substrate, and may include a plurality of pixels PXs that are defined by the gate lines GL1 to GLn and the data lines DL1 to DLm, which cross each other.

The gate lines GL1 to GLn are formed to extend in a first direction X on the first substrate 110, and are arranged to be spaced apart from each other in a second direction Y that is perpendicular to the first direction. The gate lines GL1 to GLn transfer a gate signal to a thin film transistor TFT1 to be described later.

The gate lines GL1 to GLn may be formed of any one of indium tin oxide (ITO), indium zinc oxide (IZO), and indium tin zinc oxide (ITZO). Further, the gate lines GL1 to GLn may have a two-layer structure which includes a first conductive layer that is made of the above-described material and a second conductive layer that is made of a material to be described later. The second conductive layer may be made of a metal, such as copper (Cu), molybdenum (Mo), aluminum (Al), tungsten (W), chrome (Cr), or titanium (Ti), or an alloy including at least one of the above-described metals.

The gate insulating layer 120 is formed on the first substrate 110 to cover the gate lines GL1 to GLn. The gate insulating layer 120 may be formed of an insulating material, for example, silicon nitride or silicon oxide.

The semiconductor pattern SL1 may be formed on the gate insulating layer 120 to overlap the gate lines GL1 to GLn. The semiconductor pattern SL1 may be formed in a line shape, and may include a first region SA1, a second region DA1, and a third region CA1 (“a channel region”) connecting the first region SA1 and the second region DA1 to each other.

The semiconductor pattern SL1 may be formed of amorphous silicon or polycrystalline silicon. Further, the semiconductor pattern SL1 may be formed of an oxide semiconductor material. Further, the first region SA1 and the second region DA1 of the semiconductor pattern SL1 may be heavily doped with a p-type impurity to form a source region and a drain region. Further, the third region CA1 of the semiconductor pattern SL1 may form a channel region that is not doped with an impurity. The impurity that is doped into the first region SA1 and the second region DA1 of the semiconductor pattern SL1 may be a p-type impurity such as boron (B) using B₂H₆. The impurity that is doped into the first region SA1 and the second region DA1 of the semiconductor pattern SL1 may be n-type impurities such as phosphorus (P) and arsenic (As).

The data lines DL1 to DLm are formed to substantially extend in the second direction Y on the gate insulating layer 120, and are arranged to be spaced apart from each other in the first direction X. The data lines DL1 to DLm may cross the gate lines GL1 to GLn. The data lines DL1 to DLm are insulated from the gate lines GL1 to GLn, and transfer the data signal to the thin film transistor TFT1 to be described later. The data lines DL1 to DLm include a source electrode region SEA1 that comes in contact with and overlaps the first region SA1 of the semiconductor pattern SL1.

The drain electrode DE1 is formed to be spaced apart from the source electrode region SEA1 in a plan view, and comes in contact with and overlaps the second region DA1 of the semiconductor pattern SL1.

The data lines DL1 to DLm and the drain electrode DE1 may be made of a metal, such as copper (Cu), molybdenum (Mo), aluminum (Al), tungsten (W), chrome (Cr), or titanium (Ti), or an alloy including at least one of the above-described metals.

The protection layer 130 is formed on the gate insulating layer 120 to cover the semiconductor pattern SL1, the data lines DL1 to DLm, and the drain electrode DEL The protection layer 130 may be formed of at least one of silicon nitride, silicon oxide, and silicon oxynitride. On the other hand, the protection layer 130 may further include a contact hole CH that exposes the drain electrode DEL The contact hole CH may overlap the second region DA1 of the semiconductor pattern SL1 and the drain electrode DEL

The pixel electrode PE may be formed for each pixel PX on the protection layer 130, and may be electrically connected to the drain electrode DE1 through the contact hole CH. The pixel electrode PE is not limited to the shape as illustrated in FIG. 2, but may have various shapes. The pixel electrode PE may be formed of a transparent conductive material, for example, indium tin oxide (ITO) or indium zinc oxide (IZO).

The second panel 200 may include the second substrate 210, a black matrix BM, an overcoat layer 220, and a common electrode CE.

The second substrate 210 faces the first substrate 110. The second substrate 210 may be a transparent insulating substrate.

The black matrix BM may be formed to surround each pixel PX region on the second substrate 210. The black matrix BM may overlap the gate lines GL1 to GLn, the data lines DL1 to DLm, and the thin film transistor TFT1. Although not illustrated, a color filter, which is formed to correspond to each pixel PX and is surrounded by the black matrix BM, may be arranged on the second substrate 210. The black matrix BM is formed of a light blocking material to block out unnecessary light when displaying an image. For example, the black matrix BM may prevent light leakage, which may occur at the edge of the liquid crystal layer LCL, or color mixture, which may appear at the edge of the color filter.

The overcoat layer 220 is formed on the black matrix BM and the color filter (not illustrated). The overcoat layer 220 may planarize an underlying uneven surface and serves to protect and insulate the color filter (not illustrated). The overcoat layer 220 may be formed using acrylic epoxy material.

The common electrode CE is formed on the overcoat layer 220. The common electrode CE receives a common voltage that is transferred through a common voltage line (not illustrated). The common electrode CE may be formed of a transparent conductive material, for example, indium zinc oxide (IZO) or amorphous indium tin oxide (a-ITO).

In the display device 10 having the above-described structure, the thin film transistor TFT1 is turned on and turned off in response to a driving signal that is provided through the gate line GLn. If the thin film transistor TFT1 is turned on, the data signal that is provided through the data line DLm is provided to the pixel electrode PE through the thin film transistor TFT1. Accordingly, an electric field is formed between the pixel electrode PE and the common electrode CE, and liquid crystals of the liquid crystal layer LCL are driven according to the electric field formed between the pixel electrode PE and the common electrode CE to display an image.

Hereinafter, the thin film transistor TFT1 in one pixel PX will be described in detail. The thin film transistor TFT1 is connected to the first gate line GL1 and the first data line DL1.

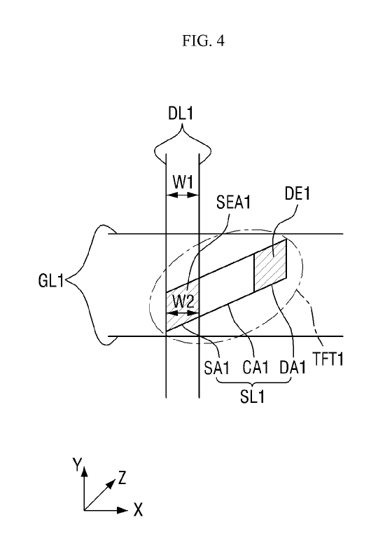

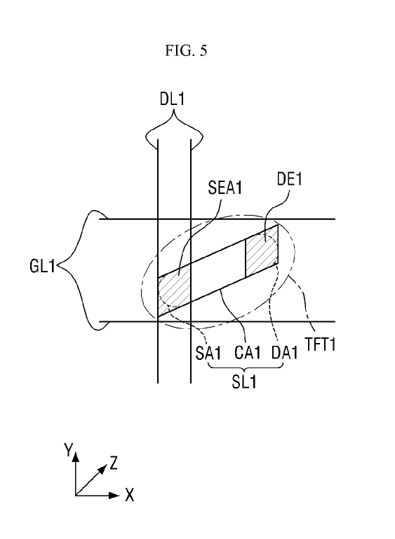

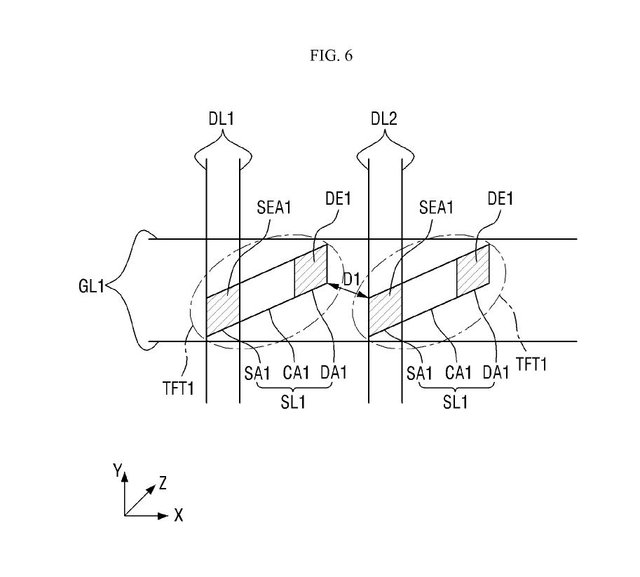

FIG. 4 is a plan view of a thin film transistor of FIG. 2, and FIG. 5 is a plan view illustrating another shape of a semiconductor pattern of FIG. 4. FIG. 6 is a plan view illustrating an arrangement of neighboring thin film transistors of FIG. 2.

Referring to FIG. 4, the thin film transistor TFT1 includes the first gate line GL1 that overlaps the semiconductor pattern SL1, the semiconductor pattern (or first semiconductor pattern) SL1, the source electrode region SEA1, and the drain electrode DEL In FIG. 4, the source electrode region SEA1 and the drain electrode DE1 are indicated as shaded portions.

The portion of the first gate line GL1 that overlaps the semiconductor pattern SL1 is the gate electrode of the thin film transistor TFT1, which applies a gate voltage to the thin film transistor TFT1 to turn on and turn off the thin film transistor TFT1.

The semiconductor pattern SL1 forms a channel of the thin film transistor TFT1. If the gate signal is applied to the portion of the first gate line GL1 that overlaps the semiconductor pattern SL1, the source electrode region SEA1 and the drain electrode DE1 are electrically connected to each other through a channel formed in the semiconductor pattern SL1 between the source electrode region SEA1 and the drain electrode DEL

The semiconductor pattern SL1 extends in a third direction Z between the first direction X and the second direction Y. The third direction is a direction other than a parallel or perpendicular direction to the gate lines or data lines. Herein, it is preferred that the angle between the semiconductor pattern SL1 and the data line is about 45° in order to prevent the line width of the black matrix parallel to the gate line from being increased while ensuring an aperture ratio of the pixel. The first region SA1, the third region CA1 and the second region DA1 may be on a straight line. Accordingly, the semiconductor pattern SL1 may not occupy a wide region in one pixel PX (in FIG. 2). The first region SA1 may come in contact with and overlap the source electrode region SEA1 of the first data line DL1, and the second region DA1 may come in contact with and overlap the drain electrode DE1. Accordingly, the region that is occupied by the thin film transistor TFT1 in one pixel PX (in FIG. 2) is reduced, and thus it becomes possible to increase the aperture ratio of the pixel in the display device.

Further, as illustrated in FIG. 6, the semiconductor pattern SL1 may be formed to secure the minimum distance D1 between adjacent semiconductor patterns SL1s (in FIG. 2) without occupying a wide region in one pixel PX (in FIG. 2). That is, the semiconductor pattern SL1 may be formed to secure the minimum distance D1 between the second region DA1 of the semiconductor pattern SL1 that overlaps the source electrode region SEA1 of the first data line DL1 and the first region SA1 of the semiconductor pattern (or second semiconductor pattern) SL1 that overlaps the source electrode region SEA1 of the second data line DL2. The minimum distance D1 may be equal to a distance that is required between exposure regions to prevent an exposure error in a process of exposing a photoresist layer when the semiconductor pattern SL1 is formed using a photolithography process. The minimum distance D1 may be equal to or larger than about 2 μm.

FIG. 4 illustrates that the first region SA1 and the second region DA1 of the semiconductor pattern SL1 completely overlap the source electrode region SEA1 of the first data line DL1 and the drain electrode DE1, respectively. However, as illustrated in FIG. 5, the first region SA1 and the second region DA1 of the semiconductor pattern SL1 may partially overlap the source electrode region SEA1 of the first data line DL1 and the drain electrode DE1, respectively. As illustrated in FIG. 4, the planar shapes of the first region SA1 and the second region DA1 of the semiconductor pattern SL1 may be the same as the planar shapes of the source electrode region SEA1 of the first data line DL1 and the drain electrode DE1, respectively. For example, the planar shapes of the first region SA1 and the second region DA1 of the semiconductor pattern SL1 may be rectangular shapes. On the other hand, as illustrated in FIG. 5, the planar shapes of the first region SA1 and the second region DA1 of the semiconductor pattern SL1 may be different from the planar shapes of the source electrode region SEA1 of the first data line DL1 and the drain electrode DE1, respectively. For example, the planar shapes of the first region SA1 and the second region DA1 of the semiconductor pattern SL1 may be partially rounded. Further, as illustrated in FIG. 5, in the case where the first region SA1 and the second region DA1 of the semiconductor pattern SL1 partially overlap the source electrode region SEA1 of the first data line DL1 and the drain electrode DE1, respectively, the areas of the first region SA1 and the second region DA1 of the semiconductor pattern SL1 may be smaller than the areas of the source electrode region SEA1 of the first data line DL1 and the drain electrode DE1, respectively.

The source electrode region SEA1 of the first data line DL1 and the drain electrode DE1 are spaced apart from each other with the intervening third region CA1 of the semiconductor pattern SL1, and come in contact with the first region SA1 and the second region DA1 of the semiconductor pattern SL1, respectively. When the thin film transistor TFT1 is turned on by the gate signal, the source electrode region SEA1 and the drain electrode DE1 receive the data signal from the first data line DL1 and provide the received data signal to the pixel electrode PE (in FIG. 3). Here, the source electrode region SEA1 of the first data line DL1 may be a partial region of the first data line DL1 to serve as the source electrode of the thin film transistor TFT1, and the width W2 of the source electrode region SEA1 may be equal to the width W1 of the first data line DL1 which does not overlap the semiconductor pattern SL1. The source electrode region SEA1 of the first data line DL1 which overlap the first region SA1 may reduce the region occupied by the thin film transistor TFT1 in one pixel PX (in FIG. 2). Accordingly, the overall size of the pixel can be reduced, and thus the display device having high resolution can be implemented.

As described above, since the display device 10 according to an embodiment of the present inventive concept is provided with the semiconductor pattern SL1 arranged in the third direction Z that is between the first direction X in which the gate line GLn extends and the second direction Y in which the data line DLm extends and the thin film transistor TFT1 including the source electrode region SEA1 that is included in the data line DLm, the minimum gap distance D1 can be secured between the semiconductor patterns SL1 between the adjacent pixels PX, and the region that is occupied by the thin film transistor TFT1 in one pixel PX can be reduced in both the first direction X and the second direction Y.

Accordingly, in the display device 10 according to an embodiment of the present inventive concept, high resolution can be implemented, and when the semiconductor pattern SL1 is formed using the photolithography process, the occurrence of the exposure error can be reduced, and the deterioration of the aperture ratio of the pixel can be reduced.

Next, a display device according to another embodiment of the present inventive concept will be described.

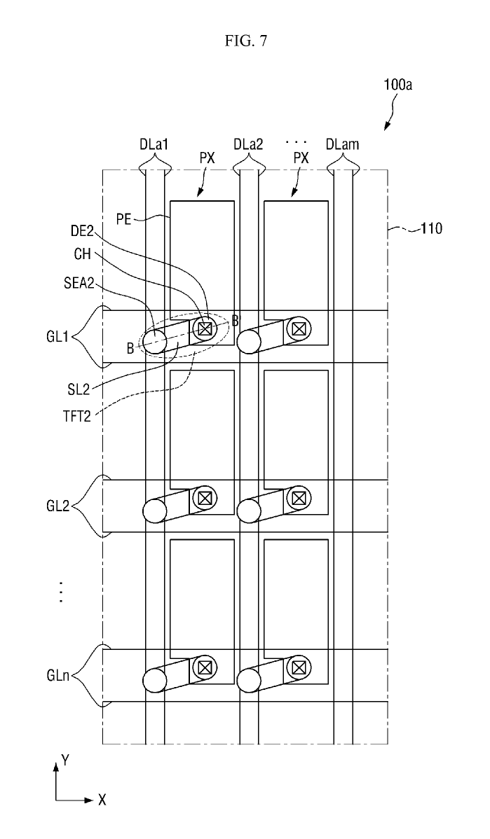

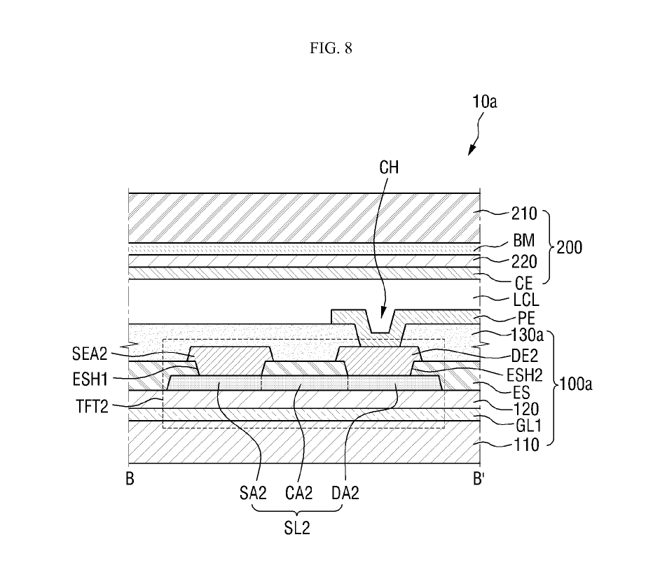

FIG. 7 is a plan view of a first display panel of a display panel according to another embodiment of the present inventive concept, and FIG. 8 is a cross-sectional view of the display panel of FIG. 7 taken along line B-B′ of FIG. 7.

A display device 10a according to another embodiment of the present inventive concept has the same configuration as the configuration of the display device 10 of FIG. 3, but only a first panel 100a is different from the first panel 100 of the display device 10 according to the above-described embodiment. Accordingly, explanation of the display device 10a according to another embodiment of the present inventive concept will be made about the first panel 100a only.

Referring to FIGS. 7 and 8, the display device 10a according to another embodiment of the present inventive concept includes a first panel 100a, a second panel 200 that faces the first panel 100a, and a liquid crystal layer LCL formed between the first panel 100a and the second panel 200. Although not illustrated, the display device 10a may further include a backlight unit that provides light to the display device 10a.

The first panel 100a may include a first substrate 110, gate lines GL1 to GLn (n is a natural number), a gate insulating layer 120, a semiconductor pattern SL2, an etch stopper layer ES, data lines DLa1 to DLam (m is a natural number), a drain electrode DE2, a protection layer 130a, and a pixel electrode PE.

Since the first substrate 110, the gate lines GL1 to GLn, and the gate insulating layer 120 have been described in detail with reference to FIGS. 2 and 3, the duplicate explanation thereof will be omitted.

The semiconductor pattern SL2 includes a first region SA2, a second region DA2, and a third region CA2 connecting the first region SA2 and the second region DA2 to each other, and is similar to the those of the semiconductor pattern SL1 of FIGS. 2 and 3. However, the shape of the semiconductor pattern SL2 is different from the shape of the semiconductor pattern SL1 of FIGS. 2 and 3. This will be described together with a thin film transistor TFT2 to be described later.

The etch stopper layer ES is formed on the gate insulating layer 120 to cover the semiconductor pattern SL2. The etch stopper layer ES serves to protect the semiconductor pattern SL2 from an etching solution that is used when the data lines DLa1 to DLam and the drain electrode DE2 are patterned and formed using the photolithography process.

The etch stopper layer ES may include a first contact-hole ESH1 and a second contact-hole ESH2 for connecting the source electrode region SEA2 included in the data lines DLa1 to DLam and the drain electrode DE2 to the first region SA2 and the second region DA2 of the semiconductor pattern SL2, respectively. The etch stopper layer ES may be formed of an insulating material, for example, silicon oxide or silicon nitride.

The data lines DLa1 to DLam are formed to extend in the second direction Y on the gate insulating layer 120, and are arranged to be spaced apart from each other in the first direction X. The data lines DLa1 to DLam are insulated from the gate lines GL1 to GLn, and transfer the data signal to the thin film transistor TFT2 to be described later. The data lines DLa1 to DLam include a source electrode region SEA2 that comes in contact with and overlaps the first region SA2 of the semiconductor pattern SL2 through the first through-hole ESH1 of the etch stopper layer ES.

The drain electrode DE2 is formed to be spaced apart from the source electrode region SEA2 in a plan view, and comes in contact with and overlaps the second region DA2 of the semiconductor pattern SL2 through the second through-hole ESH2 of the etch stopper layer ES.

The data lines DLa1 to DLam and the drain electrode DE2 may be formed of a metal, such as copper, molybdenum, aluminum, tungsten, chrome, or titanium, or an alloy including at least one of the above-described metals.

The protection layer 130a is similar to the protection layer 130 of FIG. 3. However, the protection layer 130a is formed on the etch stopper layer ES to cover the data lines DLa1 to DLam and the drain electrode DE2.

In the display device 10a having the above-described structure, the thin film transistor TFT2 is turned on in response to a driving signal that is provided through the gate line GLn. If the thin film transistor TFT2 is turned on, the data signal that is provided through the data line DLam is provided to the pixel electrode PE through the thin film transistor TFT2. Accordingly, an electric field is formed between the pixel electrode PE and the common electrode CE, and liquid crystals of the liquid crystal layer LCL are driven according to the formed electric field to display an image.

Hereinafter, the thin film transistor TFT2 in one pixel PX will be described in detail. It is exemplified that the thin film transistor TFT2 is connected to the first gate line GL1 and the first data line DLa1.

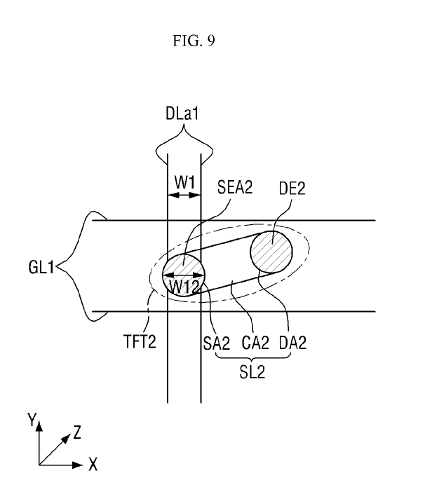

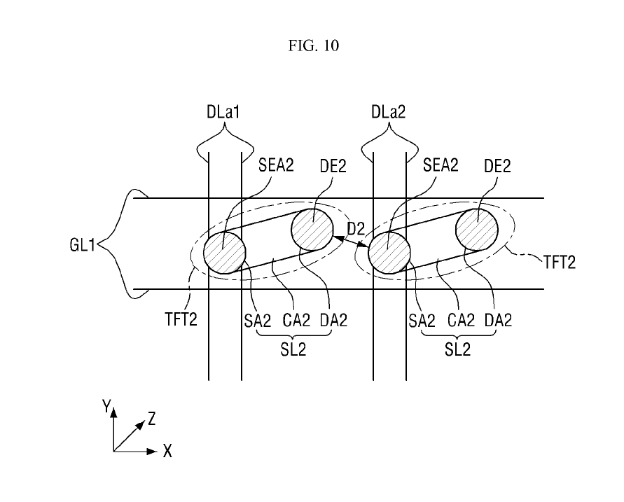

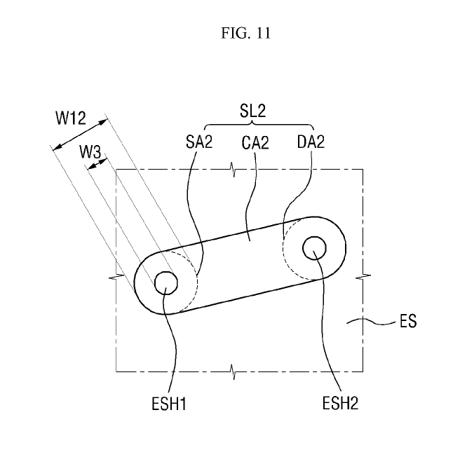

FIG. 9 is a plan view of a thin film transistor in one pixel of FIG. 7, and FIG. 10 is a plan view illustrating an arrangement of neighboring thin film transistors of FIG. 7. FIG. 11 is a plan view illustrating the arrangement of a semiconductor pattern, an etch stopper layer, a source electrode region, and a drain electrode of FIG. 8.

Referring to FIG. 9, the thin film transistor TFT2 includes the first gate line GL1 that overlaps the semiconductor pattern SL2, the semiconductor pattern (or first semiconductor pattern) SL2, the source electrode region SEA2, and the drain electrode DE2.

The portion of the first gate line GL1 that overlaps the semiconductor pattern SL2 is the gate electrode of the thin film transistor TFT2, which applies a gate signal that is supplied to the first gate line GL1 to turn on and turn off the thin film transistor TFT2.

The semiconductor pattern SL2 forms a channel of the thin film transistor TFT2. If the gate signal is applied to the first gate line GL1 that overlaps the semiconductor pattern SL2, the source electrode region SEA2 and the drain electrode DE2 are electrically connected to each other through a channel region formed in the semiconductor pattern SL2 between the source electrode region SEA2 and the drain electrode DE2.

The semiconductor pattern SL2 extends in a third direction Z between the first direction X and the second direction Y. The third direction is a direction other than a parallel or perpendicular direction to the gate lines or data lines. Herein, it is preferred that the angle between the semiconductor pattern SL2 and the data line is about 45° in order to prevent the line width of the black matrix parallel to the gate line from being increased while ensuring an aperture ratio of the pixel. Accordingly, the semiconductor pattern SL2 may not occupy a wide region in one pixel PX (in FIG. 7). The first region SA2 may come in contact with and overlap the source electrode region SEA2 of the first data line DLa1, and the second region DA2 may come in contact with and overlap the drain electrode DE2. Accordingly, the region that is occupied by the thin film transistor TFT2 in one pixel PX (in FIG. 7) is reduced, and thus it becomes possible to increase the aperture ratio of the pixel in the display device.

Further, as illustrated in FIG. 10, the semiconductor pattern SL2 may be formed to secure the minimum distance D2 between adjacent semiconductor patterns SL1s (in FIG. 7) without occupying a wide region in one pixel PX (in FIG. 7). That is, the semiconductor pattern SL2 may be formed to secure the minimum distance D2 between the second region DA2 of the semiconductor pattern SL2 that overlaps the source electrode region SEA2 of the first data line DLa1 and the first region SA2 of the semiconductor pattern (or second semiconductor pattern) SL2 that overlaps the source electrode region SEA2 of the second data line DLa2. The minimum distance D2 may be equal to a distance that is required between exposure regions to prevent an exposure error in a process of exposing a photoresist layer when the semiconductor pattern SL2 is formed using a photolithography process. The minimum distance D2 may be equal to or larger than about 2 μm.

On the other hand, the first region SA2 and the second region DA2 of the semiconductor pattern SL2 completely overlap the source electrode region SEA2 of the first data line DLa1 and the drain electrode DE2, respectively. Further, the planar shapes of the first region SA2 and the second region DA2 of the semiconductor pattern SL2 may be the same as the planar shapes of the source electrode region SEA2 of the first data line DLa1 and the drain electrode DE2, respectively. For example, they may be in a circular shape.

The source electrode region SEA2 of the first data line DLa1 and the drain electrode DE2 are spaced apart from each other with the intervening third region CA2 of the semiconductor pattern SL2, and come in contact with the first region SA2 and the second region DA2 of the semiconductor pattern SL2, respectively. When the thin film transistor TFT2 is turned on by the gate signal, the source electrode region SEA2 and the drain electrode DE2 receive the data signal from the first data line DLa1 and provide the received data signal to the pixel electrode PE (in FIG. 7). Here, the source electrode region SEA1 of the first data line DLa1 may be a partial region of the first data line DLa1 to serve as the source electrode of the thin film transistor TFT2, and thus the region that is occupied by the thin film transistor TFT2 in one pixel PX (in FIG. 7) can be reduced. Accordingly, the size of the pixel can be reduced, and thus the display device having high resolution can be implemented.

On the other hand, referring to FIG. 11, the maximum horizontal widths W12 of the source electrode region SEA2 and the drain electrode DE2 may be larger than the horizontal widths W3 of the first through-hole ESH1 and the second through-hole ESH2 of the etch stopper layer ES. Accordingly, a misalignment that may occur between the source electrode SEA2 and the first through-hole ESH1 of the etch stopper layer ES and a misalignment that may occur between the drain electrode DE2 and the second through-hole ESH2 of the etch stopper layer ES can be reduced.

However, since it is not required to consider the misalignment in portions of the first data line DLa1 except for the source electrode region SEA2, the width W1 (in FIG. 9) of the first data line DLa1 except for the source electrode region SEA2 may be smaller than the maximum width W12 (in FIG. 9) of the source electrode region SEA2. In this case, the aperture ratio of the pixel in the display device having high resolution can be increased.

As described above, since the display device 10a according to another embodiment of the present inventive concept is provided with the semiconductor pattern SL2 arranged in the third direction Z that is between the first direction X in which the gate line GLn extends and the second direction Y in which the data line DLam extends and the thin film transistor TFT2 including the source electrode region SEA2 that is included in the data line DLam, the minimum distance D2 can be secured between the semiconductor patterns SL2 between the adjacent pixels PX, and the region that is occupied by the thin film transistor TFT2 in one pixel PX can be reduced in both the first direction X and the second direction Y.

Accordingly, in the display device 10a according to another embodiment of the present inventive concept, high resolution can be implemented, and when the semiconductor pattern SL2 is formed using the photolithography process, the occurrence of the exposure error can be reduced, and the deterioration of the aperture ratio of the pixel can be reduced.

Further, according to the display device 10a according to another embodiment of the present inventive concept, since the etch stopper layer ES and the data line DLam are formed so that the width W12 of the source electrode region SEA2 is larger than the width W3 of the first through-hole ESH1 of the etch stopper layer ES, and the width W1 of the data line DLam except for the source electrode region SEA2 is smaller than the width W12 of the source electrode region SEA2, the aperture ratio of the pixel can be increased, and the misalignment between the source electrode region SEA2 and the first through-hole ESH1 of the etch stopper layer ES can be reduced.

Those skilled in the art will appreciate that many variations and modifications can be made to the embodiments without substantially departing from the principles of the present inventive concept. Therefore, the disclosed embodiments of the inventive concept are used in a generic and descriptive sense only and not for purposes of limitation.

What is claimed is:

1. A display device comprising:
a substrate;
a first gate line extending in a first direction on the substrate;
a gate insulating layer formed on the substrate to cover the first gate line;
a first semiconductor pattern formed on the gate insulating layer to overlap the first gate line, and including a first region and a second region;
a first data line extending in a second direction that is crossing the first gate line on the gate insulating layer, and including a source electrode region that overlaps the first region of the first semiconductor pattern;
a drain electrode spaced apart from the source electrode region and formed on the second region of the first semiconductor pattern; and
a pixel electrode formed on the drain electrode and electrically connected to the drain electrode, wherein the first semiconductor pattern is arranged in a third direction between the first direction and the second direction.

2. The display device of claim 1, wherein the first region and the second region of the first semiconductor pattern are on a straight line.

3. The display device of claim 1, wherein a width of the source electrode region is equal to a width of the first data line which does not overlap the first region of the first semiconductor pattern.

4. The display device of claim 1, wherein the first semiconductor pattern comprises a third region that connects the first region and the second region to each other, and
the first region and the second region of the first semiconductor pattern completely overlap the source electrode and the drain electrode, respectively.

5. The display device of claim 1, wherein the first semiconductor pattern comprises a third region that connects the first region and the second region to each other, and
the first region and the second region of the first semiconductor pattern partially overlap the source electrode and the drain electrode, respectively.

6. The display device of claim 5, wherein areas of the first region and the second region of the first semiconductor pattern are smaller than areas of the source electrode region and the drain electrode, respectively.

7. The display device of claim 1, wherein planar shapes of the first region and the second region of the first semiconductor pattern are rectangular or partially rounded.

8. The display device of claim 1, further comprising:
a second semiconductor pattern formed on the gate insulating layer to overlap the first gate line, spaced apart from the first semiconductor pattern in the first direction, and including a first region and a second region; and
a second data line extending in the second direction on the gate insulating layer, spaced apart from the first data line in the first direction, and including a source electrode region overlapping the first region of the second semiconductor pattern,
wherein the second semiconductor pattern is arranged in the third direction, and a minimum gap distance between the second region of the first semiconductor pattern and the first region of the second semiconductor pattern is equal to or larger than 2 μm.

9. The display device of claim 8, further comprising:
a second semiconductor pattern formed on the gate insulating layer to overlap the first gate line, spaced apart from the first semiconductor pattern in the first direction, and including a first region and a second region; and
a second data line that extending in the second direction on the gate insulating layer, spaced apart from the first data line in the first direction, and including a source electrode region overlapping the first region of the second semiconductor pattern,
wherein the second semiconductor pattern is arranged in the third direction, and a minimum gap distance between the second region of the first semiconductor pattern and the first region of the second semiconductor pattern is equal to or larger than 2 μm.

10. The display device of claim 1, further comprising an etch stopper layer formed on the gate insulating layer to cover the first semiconductor pattern between the first semiconductor pattern and the first data line,
wherein the etch stopper layer includes a first through-hole for connecting the source electrode region of the first data line to the first region of the first semiconductor pattern, and a second through-hole for connecting the drain electrode to the second region of the first semiconductor pattern.

11. The display device of claim 10, wherein a maximum width of the source electrode region and a maximum width of the drain electrode are larger than a width of the first through-hole and a width of the second through-hole, respectively.

12. The display device of claim 11, wherein a width of the first data line except for the source electrode region is smaller than a width of the source electrode region.

13. The display device of claim 10, wherein the first region and the second region of the first semiconductor pattern completely overlap the source electrode region and the drain electrode, respectively.

14. The display device of claim 13, wherein planar shapes of the first region and the second region of the first semiconductor pattern are circular.

15. The display device of claim 1, further comprising a protection layer interposed between the gate insulating layer and the pixel electrode, and formed to cover the first semiconductor pattern, the data lines, and the drain electrode,
wherein the protection layer includes a contact hole that overlaps the second region of the first semiconductor pattern and the drain electrode.

16. The display device of claim 1, an angle between the first semiconductor pattern and the first data line is about 45°.
